(19) United States
(12) Patent Application Publication
(10) Pub. No.: US 2024/0153990 A1
(43) Pub. Date: May 9, 2024

(54) FIELD EFFECT TRANSISTOR WITH BACKSIDE SOURCE/DRAIN CONTACT

(71) Applicant: INTERNATIONAL BUSINESS MACHINES CORPORATION, ARMONK, NY (US)

(72) Inventors: Chanro Park, Clifton Park, NY (US); Ruilong Xie, Niskayuna, NY (US); Julien Frougier, Albany, NY (US); Min Gyu Sung, Latham, NY (US); Juntao Li, Cohoes, NY (US)

(21) Appl. No.: 18/053,795

(22) Filed: Nov. 9, 2022

(51) Int. Cl. H01L 29/06; H01L 21/8238; H01L 23/48; H01L 29/417; H01L 29/423; H01L 29/66; H01L 29/775; H01L 29/786

(52) U.S. Cl. CPC H01L 29/0673; H01L 21/823807; H01L 21/823814; H01L 21/823871; H01L 23/481; H01L 29/41733; H01L 29/42392; H01L 29/66439; H01L 29/775; H01L 29/78696

(57) ABSTRACT

A semiconductor device includes a nanostructure field effect transistor (FET). The FET includes a gate and a source or drain (S/D) region. The FET also includes a backside S/D contact connected to a top surface of the S/D region. The backside S/D contact includes a lateral portion upon the top surface of the S/D region. The lateral portion further laterally extends adjacent to or past the first S/D region. The backside S/D contact includes a vertical portion that extends vertically downward from the lateral portion below the bottom surface of the substrate layer. The FET also includes a backside S/D mushroom that extends vertically downward from the vertical portion.

### BACKGROUND

The present disclosure relates to fabrication methods and resulting structures for semiconductor devices. More specifically, the present disclosure relates to fabrication methods and resulting structures for field effect transistors (FETs) with a backside source/drain (S/D) for complementary metal oxide semiconductor (CMOS) technologies.

In certain semiconductor device fabrication processes, many semiconductor devices, such as n-type field effect transistors (nFETs) and p-type field effect transistors (pFETs), may be fabricated on a single wafer. Non-planar transistor device architectures (e.g., fin-type FETs (FinFETs), gate all around (GAA) FETs, nanowire FETs, nanosheet FETs, or the like) can provide increased device density and increased performance over planar transistors. As semiconductor integrated circuits (ICs) and/or chips become smaller, the implementation of stacked nanostructure channels in semiconductor devices has increased. Nanosheets or nanowires generally refer to two-dimensional nanostructures with a thickness range on the order of about 1 nanometer (nm) to about 100 nm, and they can serve as FET channels and facilitate the fabrication of non-planar semiconductor devices having a reduced footprint compared to conventional planar-type semiconductor devices. For example, nanosheet transistors, in contrast to conventional planar FETs, include a gate stack that wraps around the full perimeter of multiple stacked nanosheet channels for a reduced device footprint and improved control of channel current flow. Nanosheet transistor configurations may enable fuller depletion in the nanosheet channel regions and reduce short-channel effects. Accordingly, nanosheets and nanowires are seen as feasible options for reducing the footprints of semiconductor transistor devices to 7 nanometers or less.

Nanosheet transistor configurations have been powered by power wire grids including power lines and ground lines. Power wire grids have been typically located above the nanosheet transistor(s), on the front side of the IC package, or the like, and generally supply power and/or ground potential to BEOL layers, overall device layers, or the like, through conductive structures, such as power grid pillars formed by through silicon vias (TSVs). However, as increasing overall device layers are included in modern IC packages, resistances increase, and IR drops (e.g., greater than 5% voltage drop) increase. In addition, TSVs used to deliver power to device layers through interconnect layers can occupy valuable routing space for signal lines, increase the resistance of interconnects and TSVs, deteriorate the performance of the IC package, and/or reduce the lifetime of the IC package.

Therefore, backside power distribution networks have been utilized to provide power and/or ground potential to backside power rails and backside ground rails, respectively. In some implementations, backside power rails and backside ground rails are still being formed from the frontside of the IC package. Such fabrication techniques have many challenges. Therefore, there is a need for efficient IC package fabrication operations to fabricate a backside contact and associated backside rail. There is also a need to improve high electrical resistances between traditional backside rails and the connected backside contact.

### SUMMARY

In an embodiment of the present disclosure, a semiconductor device is presented. The semiconductor device includes a substrate layer. The semiconductor device includes a transistor upon the substrate layer. The transistor includes one or more channel regions and a first source or drain (S/D) region upon the substrate layer and connected to the one or more channel regions. The semiconductor device includes a backside S/D contact connected to a top surface of the first S/D region. The backside S/D contact includes a lateral portion that laterally extends adjacent to or beyond the first S/D region and a vertical portion that extends vertically downward from the lateral portion below the bottom surface of the substrate layer. The semiconductor device includes a backside S/D mushroom that extends vertically downward below the vertical portion.

The backside S/D mushroom generally increases the surface area and/or volume of conductive material of backside S/D contact in associated with a backside rail, such as a backside power rail, backside ground rail. The backside S/D mushroom may be formed of a relatively different (e.g., higher conductivity) conductive material relative to the vertical portion. In this manner, the electrical impedance from the backside rail into the backside S/D contact may be relatively reduced by the backside S/D mushroom.

In an example, the vertical portion of the backside S/D contact may be located between adjacent gate cut regions of neighboring gates to comply with wiring or interconnect density constraints.

In another embodiment of the present invention, a method of forming a semiconductor device is presented. The method includes forming a source or drain (S/D) region upon a substrate layer and contacting respective first end(s) of one or more channel regions. The method further includes forming a backside S/D contact upon a top surface of the S/D region. The backside S/D contact extends laterally adjacent to or beyond the first S/D region. The backside S/D contact further extends vertically downward below the bottom surface of the substrate layer. The method includes forming a backside rail trench that exposes a portion of the backside S/D contact. The method further includes forming a backside S/D mushroom from the exposed portion of the backside S/D contact. The backside S/D mushroom extends vertically downward below the backside S/D contact.

The backside S/D mushroom generally increases the surface area and/or volume of conductive material of backside S/D contact associated with a backside rail, such as a backside power rail, backside ground rail. The backside S/D mushroom may be formed of a relatively different (e.g., higher conductivity) conductive material relative to the vertical portion. In this manner, the electrical impedance from the backside rail into the backside S/D contact may be relatively reduced by the backside S/D mushroom.

In an example, a conductive barrier liner of the backside S/D contact may be removed from the exposed portion of the backside S/D contact prior to forming the backside S/D mushroom therearound.

In another embodiment, a transistor is presented. The transistor includes one or more channel regions, a single gate that is around each of the one or more channel regions, and a source or drain (S/D) region connected to the one or more channel regions. The transistor further includes a backside S/D contact connected to a top surface of the S/D region. The backside S/D contact includes a lateral portion upon the top surface of the S/D region and that laterally extends adjacent to or beyond the first S/D region. The backside S/D contact further includes a vertical portion that extends vertically downward from the lateral portion below the bottom surface of the substrate layer. The transistor further includes a backside S/D mushroom that extends vertically downward from the vertical portion.

The above summary is not intended to describe each illustrated embodiment or every implementation of the present disclosure.

### BRIEF DESCRIPTION OF THE DRAWINGS

The drawings included in the present application are incorporated into, and form part of, the specification. They illustrate embodiments of the present disclosure and, along with the description, explain the principles of the disclosure. The drawings are only illustrative of certain embodiments and do not limit the disclosure.

FIG. 1 through FIG. 13 depicts cross-sectional views of a semiconductor device that includes a backside S/D contact at stages of the semiconductor device fabrication process, according to embodiments.

FIG. 14 depicts a method of fabricating a semiconductor device that includes a backside S/D contact, according to embodiments.

### DETAILED DESCRIPTION

The present disclosure describes nanostructure FET devices, such as a nanosheet GAA FET, and methods of fabrication of the FET devices. In particular, the present disclosure describes a FET that includes a backside S/D contact.

The flowcharts and cross-sectional diagrams in the Figures illustrate methods of fabricating FET devices according to various embodiments. In some alternative implementations, the fabrication steps may occur in a different order that that which is noted in the Figures, and certain additional fabrication steps may be implemented between the steps noted in the Figures. Moreover, any of the layered structures depicted in the Figures may contain multiple sublayers.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” means that a first element can be etched, and the second element can act as an etch stop.

For the sake of brevity, conventional techniques related to semiconductor device and IC fabrication may or may not be described in detail herein. Moreover, the various tasks and process steps described herein can be incorporated into a more comprehensive procedure or process having additional steps or functionality not described in detail herein. Various steps in the manufacture of semiconductor devices and semiconductor-based ICs are well known and so, in the interest of brevity, many conventional steps will only be mentioned briefly herein or will be omitted entirely without providing the well-known process details.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Turning now to an overview of technologies that are more specifically relevant to aspects of the present disclosure, a metal-oxide-semiconductor field-effect transistor (MOSFET) may be used for amplifying or switching electronic signals. The MOSFET has a source electrode, a drain electrode, and a metal oxide gate electrode. The metal gate portion of the metal oxide gate electrode is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field effect transistors (nFET) and p-type field effect transistors (pFET) are two types of complementary MOSFETs. The nFET includes n-doped source and drain junctions and uses electrons as the current carriers. The pFET includes p-doped source and drain junctions and uses holes as the current carriers. Complementary metal oxide semiconductor (CMOS) is a technology that uses complementary and symmetrical pairs of p-type and n-type MOSFETs to implement logic functions. As mentioned above, hole mobility on the pFET may have an impact on overall device performance.

The wafer footprint of an FET is related to the electrical conductivity of the channel material. If the channel material has a relatively high conductivity, the FET can be made with a correspondingly smaller wafer footprint. A known method of increasing channel conductivity and decreasing FET size is to form the channel as a nanostructure. For example, a GAA nanosheet FET provides a relatively small FET footprint by forming the channel region as a series of nanosheets. In a known GAA configuration, a nanosheet GAA FET includes a source region, a drain region and stacked nanosheet channels between the source and drain regions. Semiconductor nanosheet FET devices typically include one or more suspended nanosheets that serve as the channel. A gate surrounds the stacked nanosheet channels and regulates electron flow through the nanosheet channels between the source and drain regions. GAA nanosheet FETs are fabricated by forming alternating layers of channel nanosheets and sacrificial nanosheets. The sacrificial nanosheets are released from the channel nanosheets before the FET device is finalized. For n-type FETs, the channel nanosheets are typically silicon (Si) and the sacrificial nanosheets are typically silicon germanium (SiGe). For p-type FETs, the channel nanosheets can be SiGe and the sacrificial nanosheets can be Si. In some implementations, the channel nanosheet of a p-type FET can be SiGe or Si, and the sacrificial nanosheets can be Si or SiGe. Forming the GAA nanosheets from alternating layers of channel nanosheets formed from a first type of semiconductor material (e.g., Si for n-type FETs, and SiGe for p-type FETs) and sacrificial nanosheets formed from a second type of semiconductor material (e.g., SiGe for n-type FETs, and Si for p-type FETs) provides superior channel electrostatics control, which is necessary for continuously scaling gate lengths down to seven (7) nanometer CMOS technology and below.

In certain nanostructure FET devices, it has been difficult to integrate a backside S/D contact to contact the S/D from the backside of the semiconductor device. For example, in known nanostructure FET devices, a sacrificial S/D contact is initially formed prior to forming an associated S/D thereupon. Subsequently, the sacrificial S/D contact may be removed and replaced with a backside S/D contact. The removal of the sacrificial S/D contact is difficult and increases semiconductor device fabrication complexity. Therefore, it may be desirable to fabricate nanostructure FET structures with a backside S/D contact without an otherwise associated sacrificial S/D contact.

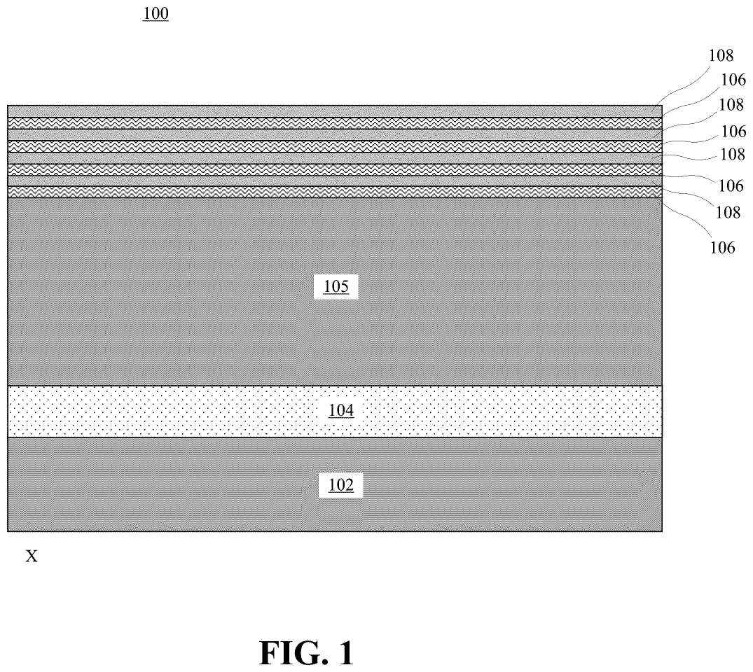

Referring now to the drawings in which like numerals represent the same or similar elements and initially to FIG. 1, this figure depicts a a cross-sectional view of a semiconductor device 100 at an intermediate stage of the fabrication process, according to embodiments.

The semiconductor device 100 may be formed over a substrate structure. The substrate structure may be a bulk-semiconductor substrate. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon (Si) is the predominantly used semiconductor material in wafer fabrication, alternative semiconductor materials can be employed, such as, but not limited to, gallium arsenide, gallium nitride, cadmium telluride, zinc selenide, and III-V compound semiconductors and/or II-VI compound semiconductors. III-V compound semiconductors are materials that include at least one element from Group III of the Periodic Table of Elements and at least one element from Group V of the Periodic Table of Elements. II-VI compound semiconductors are materials that include at least one element from Group II of the Periodic Table of Elements and at least one element from Group VI of the Periodic Table of Elements. In another implementation, as depicted, the substrate structure includes a bottom substrate 102, an insulator layer 104, and an upper substrate 105. The bottom substrate 102 and upper substrate 105 may be comprised of the silicon-containing materials suitable for the bulk-semiconductor substrate of any other suitable material(s). The insulator layer 104 may be a dielectric layer, such as an oxide, and may be referred to as a buried oxide (BOX) layer. The dielectric layer may be any suitable dielectric, oxide, or the like, and it may electrically isolate the nanostructures from the bottom substrate 102. The insulator layer 104 may be formed on the bottom substrate 102 and the upper substrate 105 may be formed upon the insulator layer 104. Thus, in various examples, bottom substrate 102 is provided, insulator layer 104 is deposited over bottom substrate 102, upper substrate 105 is deposited over the insulator layer 104, etc. Alternatively, the substrate structure may be an insulator on substrate, such as a SiGeOI (SiGe on insulator) substrate, a SOI (Silicon on insulator) substrate, or the like.

As shown in FIG. 1, after initial fabrication processing, semiconductor device 100 may include the substrate structure and alternating nanosheet stack layers that includes active semiconductor layers 108 and sacrificial layers 106.

In certain examples, the first one of the sacrificial layers 106 is initially formed directly on an upper surface of the substrate structure. In other examples, certain layers may be formed between the upper surface of the substrate structure and the first one of the sacrificial layers 106. In an example, the sacrificial layer 106 is composed of silicon-germanium (e.g., SiGe, where the Ge ranges from about 25-40%). Next, an active semiconductor layer 108 is formed on an upper surface of the first one of the sacrificial layers 106. In an example, the active semiconductor layer 108 is composed of silicon. Several additional layers of the sacrificial layer 106 and the active semiconductor layer 108 are alternately formed. In the example illustrated, there are a total of four sacrificial layers 106 and four active semiconductor layers 108 that are alternately formed. However, it should be appreciated that any suitable number of alternating layers may be formed. Although it is specifically contemplated that the sacrificial layers can be formed from SiGe and that the active semiconductor layers can be formed from Si, it should be understood that any appropriate materials can be used instead, as long as the two semiconductor materials have etch selectivity with respect to one another. As used herein, the term “selective” in reference to a material removal process denotes that the rate of material removal for a first material is greater than the rate of removal for at least another material of the structure to which the material removal process is being applied. The alternating semiconductor materials can be deposited by any appropriate mechanism. The first and second semiconductor materials (i.e., of the sacrificial layers and the active semiconductor layers) can be epitaxially grown from one another, but alternate deposition processes, such as chemical vapor deposition (CVD), physical vapor deposition (PVD), atomic layer deposition (ALD), or gas cluster ion beam (GCIB) deposition, are also contemplated.

In certain embodiments, the sacrificial layers 106 have a vertical thickness ranging, for example, from approximately 3 nm to approximately 20 nm. In certain embodiments, the active semiconductor layers 108 have a vertical thickness ranging, for example, from approximately 3 nm to approximately 20 nm. Although the range of 3-20 nm is cited as an example range of thickness, other thickness of these layers may be used. In certain examples, certain of the sacrificial layers 106 or the active semiconductor layers 108 may have different thicknesses relative to one another. For example, multiple epitaxial growth processes can be performed to form the alternating sacrificial layers 106 and the active semiconductor layers 108.

In certain embodiments, it may be desirable to have a small vertical spacing (VSP) between adjacent nanosheet layers to reduce the parasitic capacitance and to improve circuit speed. For example, the VSP (the distance between the bottom surface of a first nanosheet layer and the top surface of an adjacent second nanosheet layer) may range from 5 nm to 15 nm. However, the VSP must be of a sufficient value to accommodate the gate stack that will be formed in the spaces created by later removal of the sacrificial layers 106.

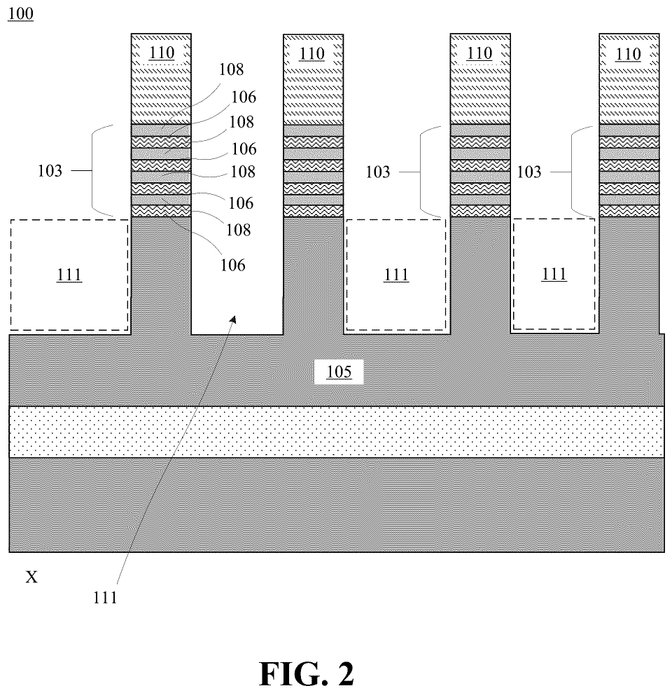

As shown in FIG. 2, after additional fabrication processing, semiconductor device 100 may include nanosheet stacks 103 that include active semiconductor layers 108 and sacrificial layers 106.

In examples, a mask layer 110 is formed on the uppermost active semiconductor layer 108. The mask layer 110 may be comprised of any suitable material(s) known to one of skill in the art. The mask layer 110 is patterned and used to perform the nanosheet stack 103 patterning process. In the nanosheet stack 103 patterning process, any suitable material removal process (e.g., reactive ion etching or RIE) may be used to remove portions of the active semiconductor layers 108 and portions of sacrificial layers 106. In examples, as depicted the patterning process may further remove portions of upper substrate 105 between neighboring nanosheet stacks 103, thereby forming one or more substrate wells 111. Following the patterning process to form the nanosheet stacks 103, the mask layer 110 is removed.

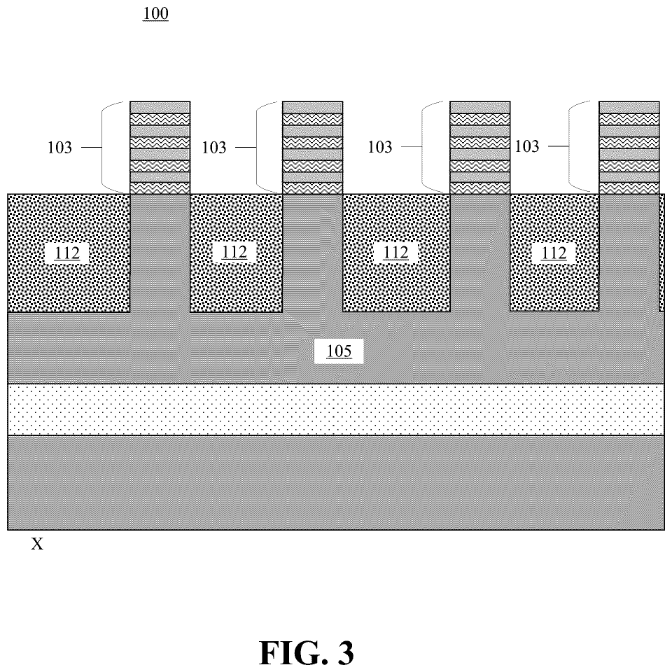

As shown in FIG. 3, after additional fabrication processing, semiconductor device 100 may include a shallow trench isolation (STI) region 112 within substrate well 111.

In examples, STI regions 112 may be formed over the upper substrate 105 and outside the footprint of nanosheet stacks 103. The STI regions 112 may be formed by depositing STI dielectric material upon the upper substrate 105 followed by STI dielectric material etch back, recess, or the like. The STI regions 112 may electrically isolate components or features of neighboring GAA FETs, or the like. In the embodiment depicted, a top surface of the one or more STI regions 112 may be coplanar with a bottom surface of one or more nanosheet stacks 103.

Subsequently, a sacrificial gate structure (not shown) is formed. In one example, a sacrificial gate (not shown) is formed by depositing a sacrificial gate oxide layer (not shown), followed by depositing a layer of amorphous silicon (a-Si) as the sacrificial gate. The sacrificial gate may be composed of polycrystalline silicon (poly silicon), amorphous silicon, and/or an oxide, such as, SiO₂. A gate hardmask (not shown) is also formed on a top side of the sacrificial gate. The gate hardmask is formed for additional nanosheet stack 103 patterning. The gate hardmask can be composed of various nitride materials including, but not limited to, a nitride, an oxide, silicon nitride (SiN), and/or a combination of a nitride material and an oxide material. In certain embodiments, sacrificial gate structures may be in parallel planes to that which is depicted, but located into and out of the page, and may be formed upon STI regions 112 around the nanosheet stacks 103. Subsequent removal of the sacrificial gate allows an access point for later removal of the sacrificial layers 106. In certain examples, gate patterning may be performed by first patterning the gate hardmask and then using the patterned gate hardmask to etch the sacrificial gates.

Subsequently, a gate spacer (not shown) is formed on the sidewalls of the patterned sacrificial gate structure. In certain embodiments, the gate spacer may be in parallel planes as that depicted into and out of the page and may be formed upon the sidewalls of the sacrificial gate structure, upon STI regions 112, and around the nanosheet stacks 103.

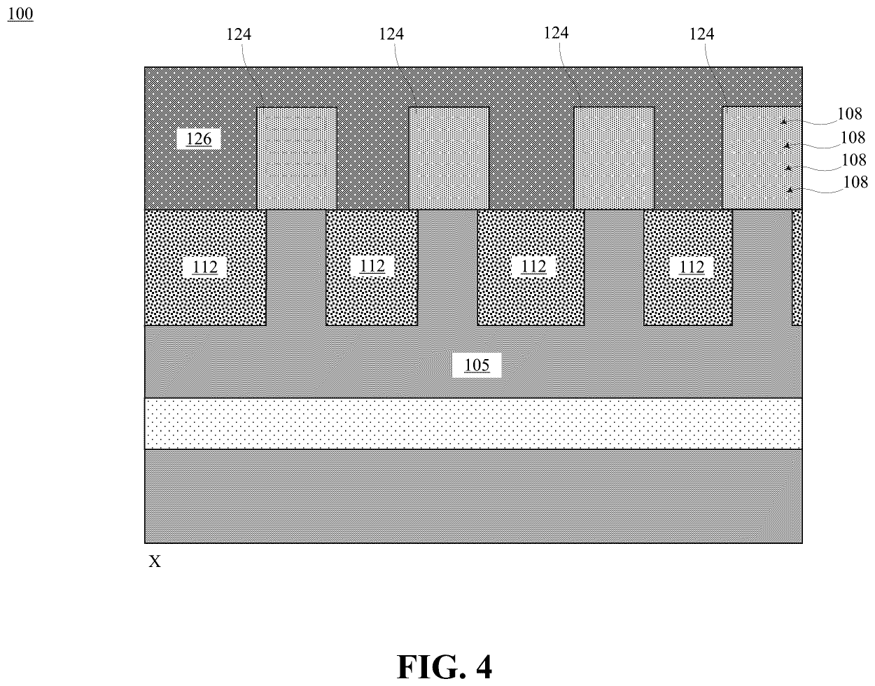

As shown in FIG. 4, after additional fabrication processing, semiconductor device 100 may include source/drain region 124 and interlayer dielectric (ILD) 126.

In examples, portions of the nanosheet stacks 103 that are not protected by the sacrificial gate structure and/or the gate spacer may be removed by removal techniques, such as etching, etc. Removal of such portions of the nanosheet stacks 103 may expose portions of the top surface of upper substrate 105 on either side (i.e., into and out of the page) of the nanosheet stacks 103, from which S/D region 124 may be subsequently formed. For clarity, at the present fabrication stage, the retained portions of nanosheet stacks 103 include alternating layers of sacrificial layers 106 and active semiconductor layers 108 generally under the sacrificial gate structure and gate spacer.

Further in examples, the semiconductor device 100 is subjected to a directional reactive ion etch (RIE) process, which can remove portions of the sacrificial layers 106 not covered by the sacrificial gate structure and the gate spacer. The RIE can use a boron-based chemistry or a chlorine-based chemistry, for example, which selectively recesses the exposed portions sacrificial layers 106 without significantly removing the active semiconductor layers 108.

Further in examples, inner spacers (not shown) are added in the recesses that were previously formed into the sacrificial layers 106. In certain embodiments, after the formation of the inner spacers, an isotropic etch process is performed to create outer vertical edges to the inner spacers that align with outer vertical edges of the active semiconductor layers. In certain embodiments, the material of the inner spacer is a dielectric material such as SiN, SiO, SiBCN, SiOCN, SiCO, etc.

Further in examples, the S/D region 124 forms either a source or a drain, respectively, upon either side of the nanostructure stack 103. S/D regions 124 may be epitaxially grown or formed. The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases are controlled and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed. For example, an epitaxially grown semiconductor material deposited on a (100) orientated crystalline surface will take on a (100) orientation. In some embodiments, epitaxial growth and/or deposition processes are selective to forming on semiconductor surfaces, and generally do not deposit material on exposed surfaces, such as silicon dioxide or silicon nitride surfaces.

The S/D region 124 may be formed by epitaxially growing a source/drain epitaxial region between neighboring nanostructure stacks 103. In some examples, S/D region 124 is formed by in-situ doped epitaxial growth. In some embodiments, the S/D region 124 epitaxial growth may overgrow the upper surface of the semiconductor device 100.

Suitable n-type dopants include but are not limited to phosphorous (P), and suitable p-type dopants include but are not limited to boron (B). The use of an in-situ doping process is merely an example. For instance, one may instead employ an ex-situ process to introduce dopants into the source and drains. Other doping techniques can be used to incorporate dopants in the bottom source/drain region. Dopant techniques include but are not limited to, ion implantation, gas phase doping, plasma doping, plasma immersion ion implantation, cluster doping, infusion doping, liquid phase doping, solid phase doping, in-situ epitaxy growth, or any suitable combination of those techniques. In preferred embodiments, the S/D epitaxial growth conditions that promote in-situ Boron doped SiGe for p-type transistor and phosphorus or arsenic doped silicon or Si:C for n-type transistors. The doping concentration in the S/D region 124 can be in the range of 1×10¹⁹ cm⁻³ to 2×10²¹ cm⁻³, or preferably between 2×10²⁰ cm⁻³ to 7×10²⁰ cm⁻³.

In certain implementations, the S/D region 124 may be partially recessed such that an upper portion of the S/D region 124 are removed. For example, the upper portion of the one or more S/D regions 124 may be etched or otherwise removed. The etch may be timed or otherwise controlled to stop the removal of S/D region 124 such that the top surface of S/D region 124 is above the upper surface of the topmost active semiconductor layer 108.

In further examples, the ILD 126 may be formed upon STI regions 112 and around the S/D regions 124. The ILD 126 may be formed by depositing a dielectric material upon S/D regions 124 and upon the STI regions 112. The ILD 126 can be any suitable material, such as, for example, porous silicates, carbon doped oxides, silicon dioxides, silicon nitrides, silicon oxynitrides, or other dielectric materials. Any known manner of forming the ILD 126 can be utilized. The ILD 126 can be formed using, for example, CVD, plasma enhanced chemical vapor deposition (PECVD), ALD, flowable CVD, spin-on dielectrics, or PVD.

In an example, the ILD 126 may be formed to a thickness above the top surface of the semiconductor device 100 and subsequently etched back such that the top surface of the ILD 126 is coplanar with a top surface of the gate hardmask and/or a top surface of gate spacer(s). In another example, another planarization process, such as a CMP, may be performed to create a planar surface for the semiconductor device 100.

In further examples, the sacrificial gate structure is removed, the sacrificial oxide layer is removed, the sacrificial layers 106 are removed, and replacement gate structure 135 is formed in place thereof.

The sacrificial gate structure may be removed by any suitable material removal process known to one of skill in the art. For example, such removal may be accomplished by an etching process which may include a dry etching process such as, for example, reactive ion etching, plasma etching, ion etching or laser ablation. The etching can further include a wet chemical etching process in which one or more chemical etchants are used to remove portions of the blanket layers that are not protected by the patterned photoresist. Then, the sacrificial layers 106 are removed (or released). Thus, there are void spaces between the active semiconductor layers 108 due to the removal of the sacrificial layers 106. It should be appreciated that during the removal of the sacrificial gate 116, the sacrificial oxide layer, and the sacrificial layers 106, appropriate etchants are used that do not significantly remove material of active semiconductor layers 108. The dry and wet etching processes can have etching parameters that can be tuned, such as etchants used, etching temperature, etching solution concentration, etching pressure, source power, RF bias voltage, RF bias power, etchant flow rate, and other suitable parameters. Dry etching processes can include a biased plasma etching process that uses a chlorine-based chemistry. Other dry etchant gasses can include Tetrafluoromethane (CF4), nitrogen trifluoride (NF3), sulfur hexafluoride (SF6), and helium (He), and Chlorine trifluoride (ClF3). Dry etching can also be performed anisotropically using such mechanisms as DRIE (deep reactive-ion etching). Chemical vapor etching can be used as a selective etching method, and the etching gas can include hydrogen chloride (HCl), Tetrafluoromethane (CF4), and gas mixture with hydrogen (H2). Chemical vapor etching can be performed by CVD with suitable pressure and temperature.

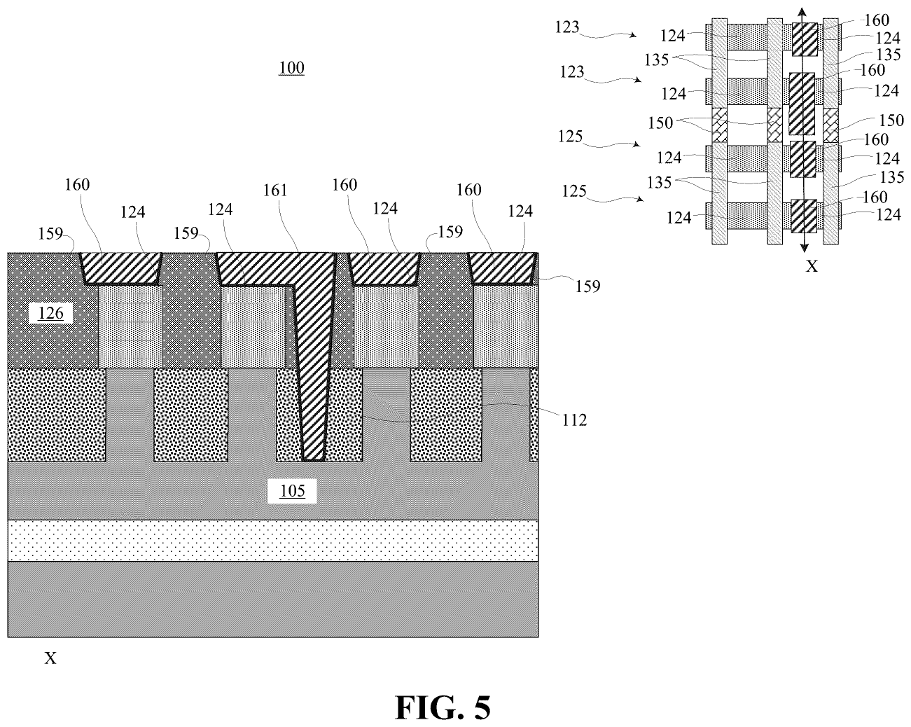

Replacement gate structure 135, shown for example in FIG. 5, may be formed by initially forming an interfacial layer (not shown) on the interior surfaces of the gate spacer and the interior surfaces of the active semiconductor layers 108 and the inner spacers. Then, a high-K layer (not shown) is formed to cover the surfaces of exposed surfaces of the interfacial layer. The high-κ layer can be deposited by any suitable techniques, such as ALD, CVD, metal-organic CVD (MOCVD), physical vapor deposition (PVD), thermal oxidation, combinations thereof, or other suitable techniques. A high-K dielectric material is a material with a higher dielectric constant than that of SiO₂, and can include e.g., LaO, AlO, ZrO, TiO, Ta₂O₅, Y₂O₃, SrTiO₃(STO), BaTiO₃(BTO), BaZrO, HfZrO, HfLaO, HfSiO, LaSiO, AlSiO, HfTaO, HfTiO, (Ba,Sr)TiO₃(BST), Al₂O₃, Si₃N₄, oxynitrides (SiON), or other suitable materials. The high-K layer can include a single layer or multiple layers, such as metal layer, liner layer, wetting layer, and adhesion layer. In other embodiments, the high-K layer can include, e.g., Ti, Ag, Al, TiAlN, TaC, TaCN, TaSiN, Mn, Zr, TiN, TaN, Ru, Mo, Al, WN, Cu, W, or any suitable materials.

Replacement gate structure 135 may be further formed by depositing a work function metal (WFM) gate (or replacement gate). The WFM gate can be comprised of metals, such as, e.g., copper (Cu), cobalt (Co), aluminum (Al), platinum (Pt), gold (Au), tungsten (W), titanium (Ti), nitride (N) or any combination thereof. The metal can be deposited by a suitable deposition process, for example, chemical vapor deposition (CVD), plasma enhanced chemical vapor deposition (PECVD), physical vapor deposition (PVD), plating, thermal or e-beam evaporation, or sputtering. In various exemplary embodiments, the height of the WFM gate can be reduced by chemical-mechanical polishing (CMP) and/or etching. Therefore, the planarization process can be provided by CMP. Other planarization process can include grinding and polishing. In general, the work function metal (WFM) gate sets the threshold voltage (Vt) of the device, a high-K gate dielectric material separating the WFM gate from the nanostructure channel (i.e., active semiconductor layers 108), and other metals that may be desired to further fine tune the effective work function (eWF) and/or to achieve a desired resistance value associated with current flow through the gate stack in the direction parallel to the plane of the nanostructure channel.

Gate cut 150 regions, depicted in FIG. 5, physically and at least partially electrically separates the gate structure (e.g., electrically and physical separates the applicable single gate into two electrically distinct gates). Initially, gate cut 150 regions may be formed by forming a gate cut trench by removing portion(s) of replacement gate structure 135, within the location of the gate cut region stopping at the top surface of STI regions 112 and/or upper substrate 105. The undesired portions of these applicable material(s) may be removed removal techniques such as e.g., depositing and patterning a gate cut mask, lithography, etching, or the like.

Subsequently, gate cut 150 region is formed within the gate cut trench. Gate cut 150 region may be a dielectric material, such as, for example, porous silicates, carbon doped oxides, silicon dioxides, silicon nitrides, silicon oxynitrides, or other dielectric materials. In an example, as depicted, gate cut 150 region may be connected to and separate a one or more replacement gate structure 135 of a p-type FET 123 from a one or more replacement gate structures 135 of a n-type FET 125.

Continuing, with reference to FIG. 5, this figure is a cross-sectional view of semiconductor device 100 after additional fabrication operations, where one or more S/D contacts 160 is formed and wherein one or more backside S/D contact(s) are formed. The top-down view depicted in FIG. 5 references a cross-sectional plane of the cross-sectional views of FIG. 1 through FIG. 13.

In examples, S/D contact 160 and backside S/D contact 161 are formed by forming respective S/D contact trenches within ILD 126 and within STI region(s) 112, respectively, and depositing conductive material within the S/D contact trench over a respective S/D region 124. Each S/D contact 160 and each backside contact 161 may consist of a silicide liner 159, such as NiSi, TiSi₂, WSi₂, PtSi, etc., a metal adhesion liner (not shown), such as TiN, TaN, etc., and a conductive metal fill, such as Al, Ru, W, Co, Cu, etc. upon the liner(s). The formation of S/D contact 160 and backside contact 161 may include etching the ILD 126 and STI region 112, respectively, to form openings, deposition of material(s), and performing a planarization process, such as a CMP process or a mechanical grinding process, to remove excess portions of the S/D contact 160 and backside contact 161. Subsequently, the top surface of S/D contact 160 and backside contact 161 and the top surface of ILD 126 may be coplanar. S/D contact 160 and backside contact 161 may be formed during middle of the line (MOL) processes.

The etching process to form the S/D contact trench(es) can include a wet chemical etching process in which one or more chemical etchants are used to remove portions of ILD 126, portions of the STI region 112, that are not protected by an associated patterned mask. In examples, the S/D region 124 and upper substrate 105 may be utilized as an etch stop.

It should be appreciated that appropriate etchants are used, or other etch parameters are selected, to retain the S/D region 124, upper substrate 105, and/or the like during the removal of some portions of ILD 126, and STI region 112, respectively. The etching processes can have etching parameters that can be tuned, such as etchants used, etching temperature, etching solution concentration, etching pressure, source power, RF bias voltage, RF bias power, etchant flow rate, etchant exposure time, and other suitable parameters. Dry etching processes can include a biased plasma etching process that uses a chlorine-based chemistry. Other dry etchant gasses can include Tetrafluoromethane (CF₄), nitrogen trifluoride (NF₃), sulfur hexafluoride (SF₆), and helium (He), and Chlorine trifluoride (ClF₃). Dry etching can also be performed anisotropically using such mechanisms as DRIE (deep reactive-ion etching). Chemical vapor etching can be used as a selective etching method, and the etching gas can include hydrogen chloride (HCl), Tetrafluoromethane (CF₄), and gas mixture with hydrogen (H₂). Chemical vapor etching can be performed by CVD with suitable pressure and temperature.

For clarity, S/D contact 160 is formed upon and contacts a top surface of a respective S/D region 124. S/D contact 160 may serve as a contact or landing pad for additional back end of the line (BEOL) wiring structures. In examples, as depicted, each S/D contact 160 may extend vertically from and above the associated S/D region 124.

For clarity, backside S/D contact 161 includes an upper portion that is formed upon and contacts a top surface of an associated S/D region 124 and a lower portion that extends from the upper portion below the bottom surface of the associated S/D region 124. Generally, backside S/D contact 161 may serve as a contact or landing pad for backside wiring structures, such as a backside power rail, backside ground rail, or the like. In examples, as depicted, the upper portion of backside S/D contact 161 may extend vertically from and above the associated S/D region 124 and laterally away from the associated S/D region 124. In examples, as depicted, the lower portion of backside S/D contact 161 may extend vertically downward from the upper lateral portion of backside S/D contact 161. In examples, as depicted, the bottom most surface of the lower portion of backside S/D contact 161 may be coplanar with the bottom of the STI region 112 at the bottom of substrate well 111. As depicted, in the top-down view of FIG. 5, the upper lateral portion of backside S/D contact 161 and the lower portion of backside S/D contact 161 may be located between neighboring gate cut 150 regions, to ease semiconductor device 100 wiring or interconnection complexities.

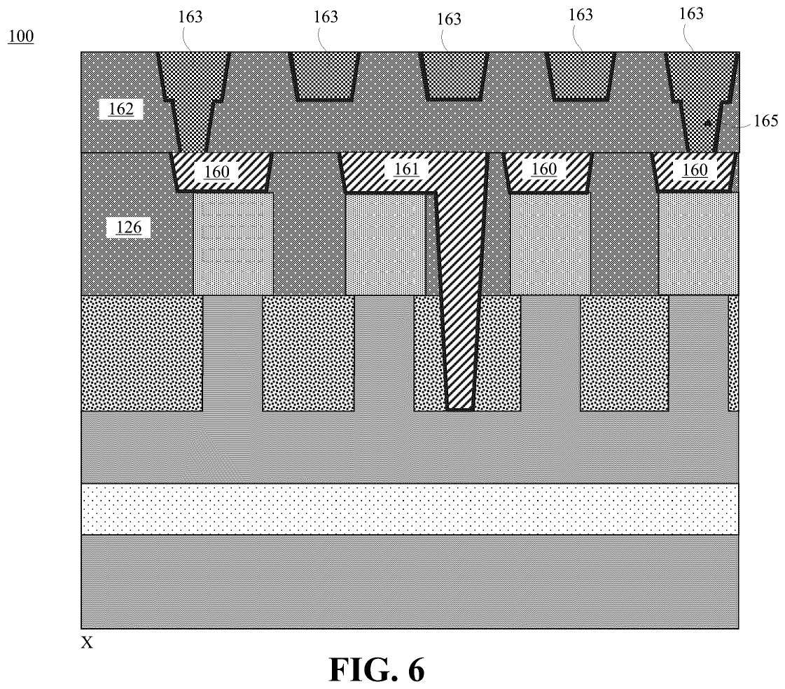

Referring now to FIG. 6, this figure is a cross-sectional view of semiconductor device 100 after additional fabrication operations, where a first BEOL level 162 is formed.

First BEOL level 162 includes metallization feature(s) 163 within the level, associated metallization dielectric layer(s), VIAs 165 that connect the metallization feature(s) 163 within with an underlying device or structure, and/or conductive bonding pads, or the like, such as S/D contact 160. Metallization feature(s) 163 may be a conductive wire, conductive trace, conductive plane, or the like.

In examples, metallization feature 163 and VIA 165 may be formed by forming a trench within metallization dielectric layer(s) and depositing conductive material within the trench. A trench may expose a portion of an underlying S/D contact 160. Each metallization feature 163 and VIA 165 may consist of one or more conductive liners, such as TiN, TaN, etc., and a conductive metal fill, such as Al, Ru, W, Co, Cu, etc. The formation of metallization feature 163 and VIA 165 may include etching the metallization dielectric layer(s) to form openings, deposition of material(s), and performing a planarization process, such as a CMP process or a mechanical grinding process, to remove excess portions of the metallization feature 163 and VIA 165. Subsequently, the top surface of metallization feature 163 and VIA 165 and the top surface of metallization dielectric layer(s) may be coplanar. Formation of metallization feature 163 and VIA 165 may utilize single damascene techniques, dual damascene techniques, etc. In some examples, as depicted a S/D contact 160 may contact and connect the source or drain (i.e., S/D region 124) of the first FET to metallization feature 163 located within the lowest or first BEOL level 162.

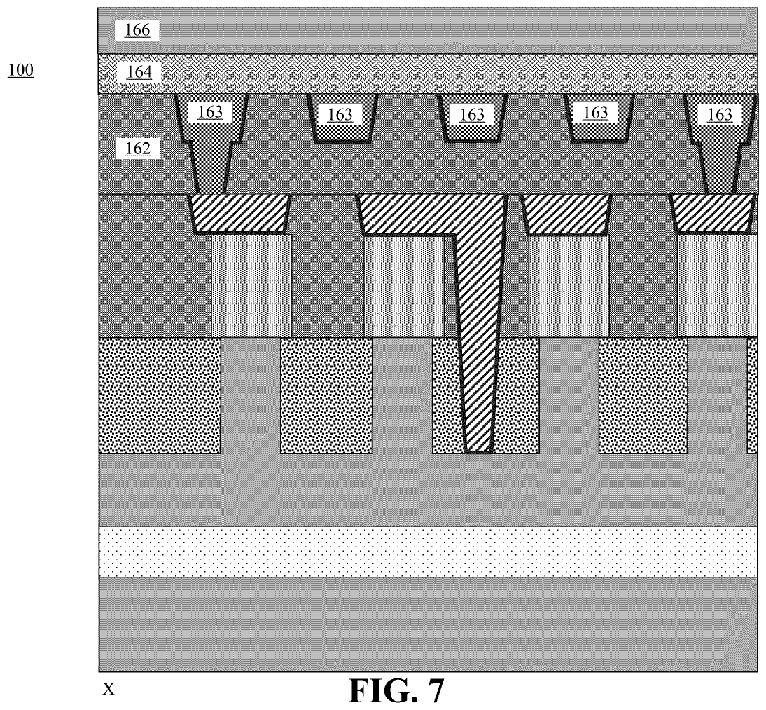

Referring now to FIG. 7, this figure is a cross-sectional view of semiconductor device 100 after additional fabrication operations, where additional BEOL levels 164 are formed. In some examples, there may be 5 metal levels M₀-M₄ between the first BEOL level 162 and the BEOL levels 164. In some examples, there may be more than 10 metal levels M₀-Mₓ between the first BEOL level 162 and the BEOL levels 164.

For clarity, in examples, as backside S/D contact 161 is connected to a backside wiring or metallization feature, such as a power rail, ground rail, or the like, no metallization feature 163, VIA 165, or the like within first BEOL level 162 and the BEOL levels 164 may directly contact or connect with backside S/D contact 161.

Upon completion of BEOL levels 164, carrier wafer 166 may be bonded or otherwise attached to the top surface or front side of BEOL levels 164, as depicted. Carrier wafer 166 may be attached to semiconductor device 100 by any carrier bonding technique.

For clarity, semiconductor device 100 may undergo similar processes, utilized to fabricate S/D contact 160, to form a gate contact, such that the gate contact may contact and extend vertically upward from the replacement gate structure 135 and may connect with a metallization feature 163 within the first BEOL level 162, the BEOL levels 164, etc.

For clarity, semiconductor device 100 may undergo similar processes, utilized to fabricate the depicted first backside S/D contact 161 that contacts and extends below a first S/D region 124 (e.g., source region) of a first FET or associated group of FETs, to form another second backside S/D contact 161 in a plane into or out of the page, such that the second backside S/D contact 161 may contact and extend below a second S/D region (e.g., drain region) of the same first FET or associated group of FETs. In example, the first backside S/D contact 161 may be connected to a backside power rail and the second backside S/D contact 161 may be connected to a backside ground rail.

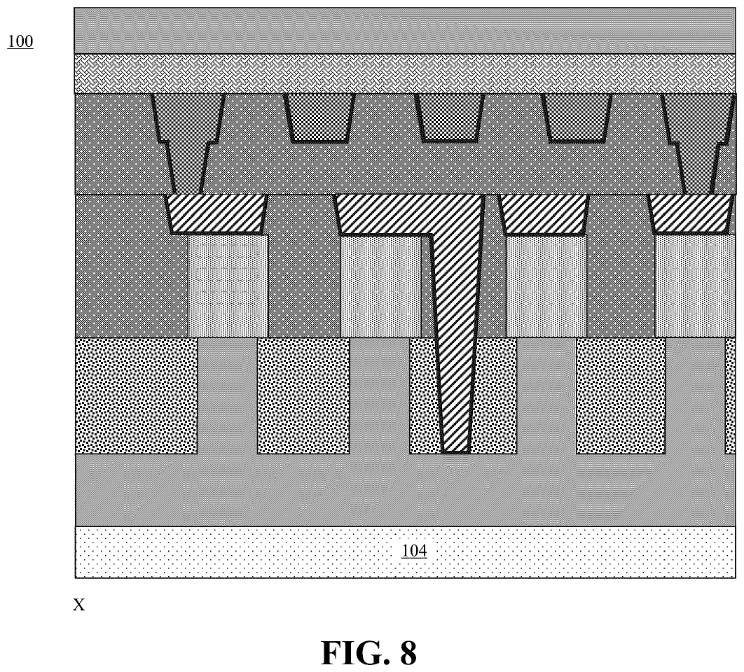

Referring now to FIG. 8, this figure depicts cross-sectional views of the semiconductor device 100 after additional fabrication operations where a bottom substrate 102 is removed. For example, semiconductor device 100 may be flipped for removal of bottom substrate 102 and further backside processing, though the orientation of semiconductor device 100 depicted in the drawings remains consistent throughout. The bottom substrate 102 may be removed by any removal technique, such as a combination of wafer grinding, CMP, dry and wet etch. Removal of bottom substrate 102 exposes the bottom surface of insulator layer 104.

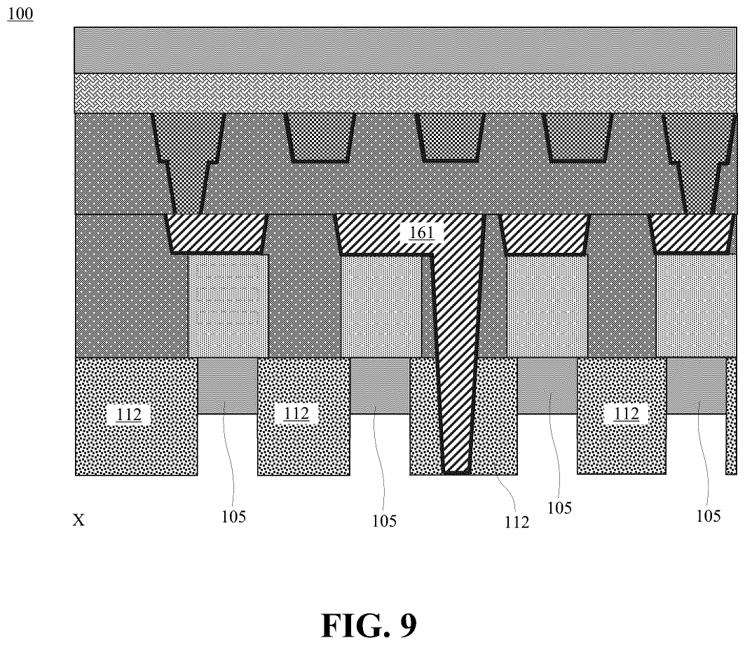

Referring now to FIG. 9, this figure depicts cross-sectional views of the semiconductor device 100 after additional fabrication operations where insulator layer 104 is removed and upper substrate 105 is partially recessed.

The insulator layer 104 may be removed by any removal technique, such as a combination of wafer grinding, CMP, dry and wet etch. Removal of insulator layer 104 exposes the bottom surface of insulator layer 104. In examples, the bottom substrate 102 and insulator layer 104 may be removed in the same sequence. Alternatively, the bottom substrate 102 and insulator layer 104 may be removed in the sequential sequences. Upon the removal of insulator layer 104 the upper substrate 105 is exposed.

Upon exposure of upper substrate 105, upper substrate 105 is partially recessed by an etch or other removal technique. The etching process to partially remove upper substrate 105 can include a wet chemical etching process in which one or more chemical etchants are used to remove portions of upper substrate 105. It should be appreciated that appropriate etchants are used, or other etch parameters are selected, to retain portions of upper substrate 105 below S/D regions 124, respectively, during the partial removal of upper substrate 105. The etching processes can have etching parameters that can be tuned, such as etchants used, etching temperature, etching solution concentration, etching pressure, source power, RF bias voltage, RF bias power, etchant flow rate, etchant exposure time, and other suitable parameters to retain portions of upper substrate 105 below S/D regions 124.

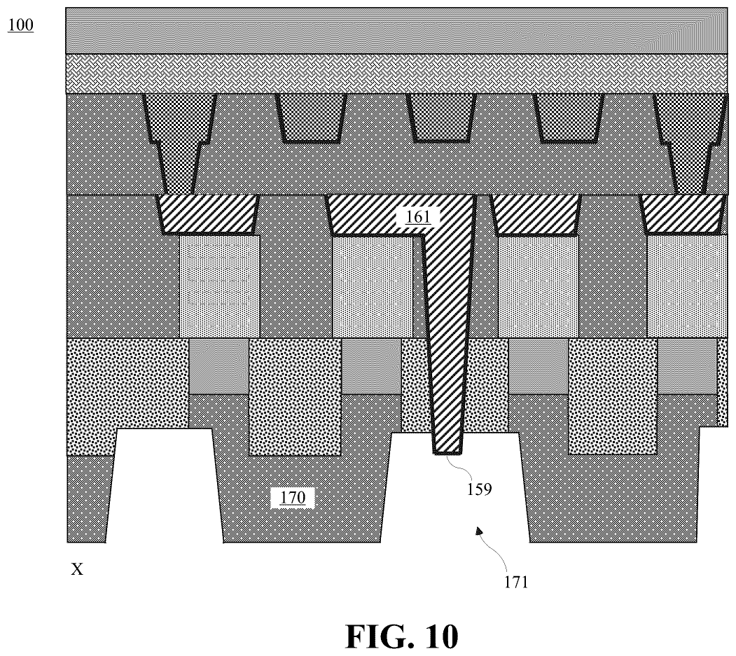

Referring now to FIG. 10, this figure is a cross-sectional view of semiconductor device 100 after additional fabrication operations, where backside rail trench 171 is formed. Backside rail trench 171 is formed by depositing ILD 170 and forming the backside rail trench 171 therein.

The ILD 170 may be formed upon the bottom surface of the semiconductor device 100, as depicted in FIG. 9. The ILD 170 may be formed by depositing a dielectric material, such as, for example, porous silicates, carbon doped oxides, silicon dioxides, silicon nitrides, silicon oxynitrides, or other dielectric materials. Any known manner of forming the ILD 170 can be utilized. The ILD 170 can be formed using, for example, CVD, PECVD, ALD, flowable CVD, spin-on dielectrics, or PVD.

The etching process to form the backside rail trench 171 can include a wet chemical etching process in which one or more chemical etchants are used to remove portions of ILD 170, portions of the STI region 112, that are not protected by an associated patterned mask. The removal of the portion of ILD 170 and portion of the STI region 112 to form backside rail trench 171 generally exposes a bottom portion of backside S/D contact 161. The exposed bottom portion of backside S/D contact 161 may include the bottom surface of backside S/D contact 161, portions of sidewall(s) of backside S/D contact 161, etc., as depicted. In other words, a bottom portion of backside S/D contact 161 may protrude into the backside rail trench 171.

It should be appreciated that appropriate etchants are used, or other etch parameters are selected, to remove the desired portion of ILD 170 and portion of the STI region 112 while retaining and exposing the bottom portion of backside S/D contact 161. The etching processes can have etching parameters that can be tuned, such as etchants used, etching temperature, etching solution concentration, etching pressure, source power, RF bias voltage, RF bias power, etchant flow rate, etchant exposure time, and other suitable parameters.

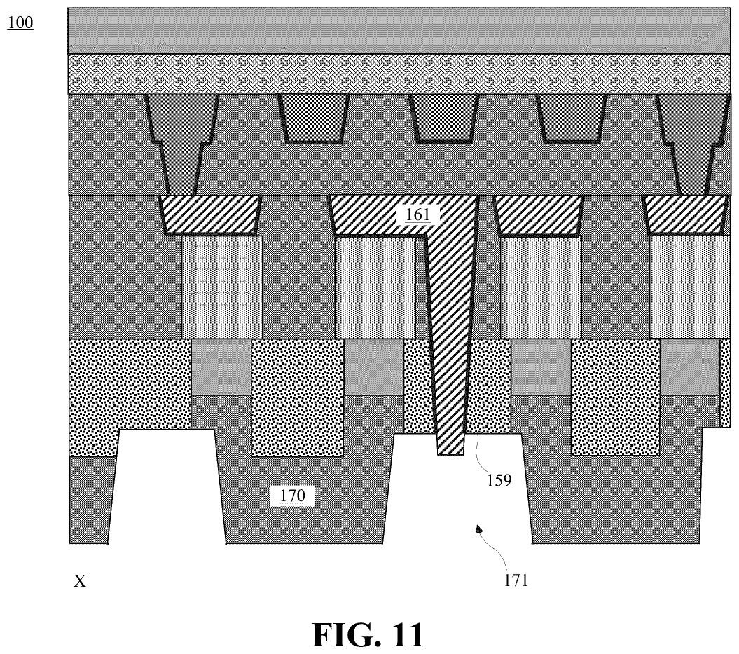

Referring now to FIG. 11, this figure is a cross-sectional view of semiconductor device 100 after additional fabrication operations, where silicide liner 159 is removed from the exposed bottom portion of backside S/D contact 161 within backside rail trench 171. The exposed silicide liner 159 may be removed by an etch and generally exposes the internal metal (e.g., metal adhesion liner, conductive metal fill, etc.) of backside S/D contact 161 within backside rail trench 171.

The etching process to remove silicide liner 159 from the exposed bottom portion of backside S/D contact 161 can include a wet chemical etching process in which one or more chemical etchants are used to remove silicide liner 159. The removal of this portion of silicide liner 159 generally exposes the internal metal material of backside S/D contact 161 within backside rail trench 171.

It should be appreciated that appropriate etchants are used, or other etch parameters are selected, to remove the desired silicide liner 159 while retaining and exposing the internal metal material of backside S/D contact 161, STI region 112, and/or ILD 170.

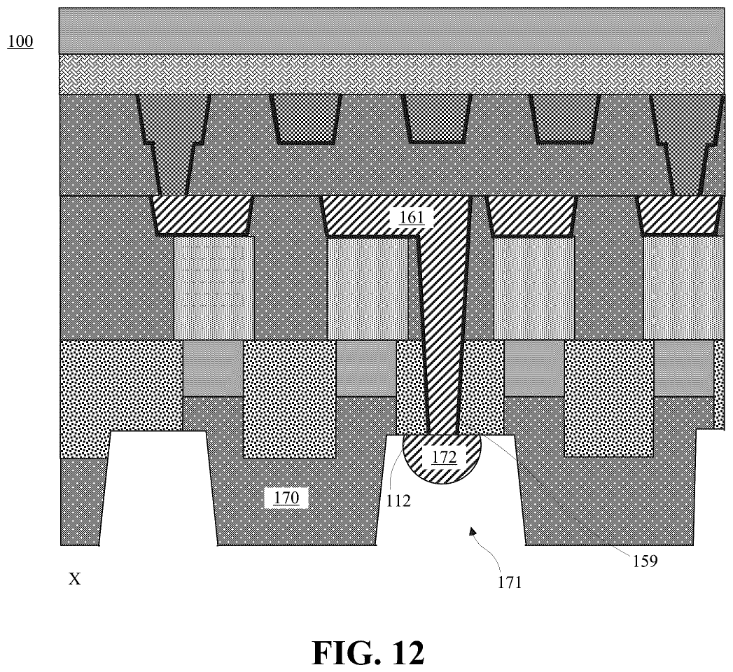

Referring now to FIG. 12, this figure is a cross-sectional view of semiconductor device 100 after additional fabrication operations where the exposed bottom portion of backside S/D contact 161 is enlarged by forming S/D contact mushroom 172 therearound.

S/D contact mushroom 172 may be formed by depositing a conductive metal around the exposed bottom portion of backside S/D contact 161 by a suitable deposition process, for example, CVD, PECVD, PVD, plating, thermal or e-beam evaporation, sputtering, or the like. The conductive metal may be Al, Ru, W, Co, Cu, etc. In an example, S/D contact mushroom 172 may be the same conductive metal relative to the conductive fill of backside S/D contact 161.

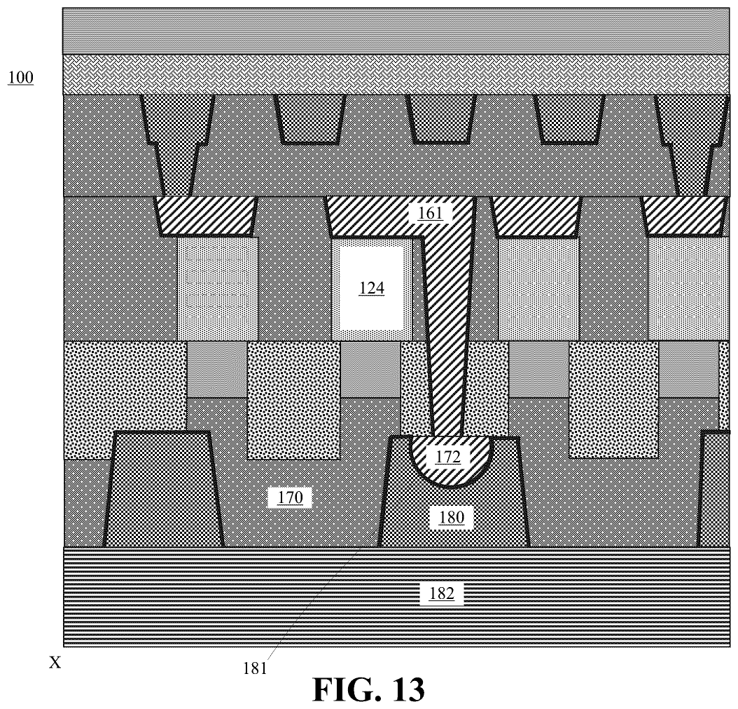

Generally, in forming S/D contact mushroom 172, the surface area and/or volume of the conductive material of backside S/D contact 161 within backside rail trench 171 is increased. In this manner, the electrical impedance from backside rail 180, shown in FIG. 13, and backside S/D contact 161, or vice versa, may be reduced. In an example, the conductive metal S/D contact mushroom 172 may be selected to have a higher conductivity relative to the conductive fill of backside S/D contact 161 to further relatively reduce the electrical impedance from backside rail 180, shown in FIG. 13, and backside S/D contact 161, or vice versa.

In examples, as depicted, S/D contact mushroom 172 may be formed upon a portion of a top surface of the backside rail trench 171. In other words, S/D contact mushroom 172 may be formed upon a portion of the bottom surface of STI region 112. In some examples, also depicted, another portion of the bottom surface of STI region 112 may be maintained and not covered by the formation of S/D contact mushroom 172. For example, a perimeter of the bottom surface of STI region 112 may be maintained and not covered by the formation of S/D contact mushroom 172. In this way, a largest diameter of S/D contact mushroom 172 may be smaller than the smallest diameter of backside rail trench 171.

Referring now to FIG. 13, this figure is a cross-sectional view of semiconductor device 100 after additional fabrication operations where backside rail 180 is formed around S/D contact mushroom 172 within backside rail trench 171 and where back side power distribution network (BSPDN) 182 is formed.

Backside rail 180 may consist of a metal, such as copper, aluminum, tungsten, cobalt, metal alloys thereof, or the like. In some examples, backside rail 180 may be a power rail (e.g., VDD power plane, etc.), ground rail (VSS power plane, etc.), or the like. Backside rail 180 may include an internal conductive region and a conductive barrier liner 181 between the sidewalls and upper surfaces of the conductive regions and the ILD 170, STI region 112, and/or S/D contact mushroom 172, respectively. The conductive barrier liner 181 may be formed of titanium, titanium nitride, tantalum, tantalum nitride, cobalt, a combination thereof, or the like. The internal conductive regions may be formed of metals such as copper, aluminum, tungsten, cobalt, alloys thereof, or the like. For clarity, the conductive barrier liner 181 of backside rail 180 may be formed around the permitter of S/D contact mushroom 172.

The formation of backside rail 180 may include etching the ILD 170, STI region 112, etc. to form backside rail trench 171, forming a blanket conductive barrier layer extending into the backside rail trench 171, depositing a metallic or conductive material over the blanket conductive barrier layer, and performing a planarization process, such as a CMP process or a mechanical grinding process, to remove excess portions of the conductive barrier layer and the conductive material. Subsequently, the bottom surface of backside rail 180 and the bottom surface of ILD 170 may be coplanar. BSPDN 182 includes power distribution network features and/or structures to adequately provide power potential, ground potential, or the like, to backside rail 180. For example, BSPDN 182 includes similar metallization feature(s) 163, VIA(s) 165, or the like as those depicted within the first BEOL level 162, the BEOL levels 164, etc.

In this manner, BSPDN 182 may be connected to S/D region 124 by way of backside rail 180, S/D contact mushroom 172, S/D contact 161, etc. For clarity, BSPDN 182 may be connected to the other S/D region 124 of the same FET, group of FETs, by way of a second backside rail 180, second S/D contact mushroom 172, second S/D contact 161, etc. that are in a different plane (e.g., a plane into or out of the page, etc.).

For clarity, as depicted, semiconductor device 100 may include a FET with a first S/D region 124 and associated backside S/D contact 161 that is upon a top surface of the first S/D region 124. The backside S/D contact 161 extends laterally away from the first S/D region 124 and extends vertically downward at least below the bottom surface of the first S/D region 124. The backside S/D contact 161 may include a S/D contact mushroom 172 which may relatively reduce the electrical impedance from backside rail 180 into backside S/D contact 161, or vice versa. The backside S/D contact 161 is electrically connected to a backside rail 180 generally below the FET. The backside rail 180 is electrically connected to metallization feature(s) within BSPDN 182 below the backside rail 180. A liner of the backside rail 180 may be formed around the S/D contact mushroom 172. In examples, the FET includes a second S/D region 124 and may include a S/D contact that may extend vertically above the second S/D region 124 and may electrically connect with metallization features within BEOL layers. In alternative examples, the FET includes a second S/D region 124 and may include a second backside S/D contact 161 that may extend vertically above the second S/D region 124, may extend laterally adjacent to the second S/D region 124, and may extend vertically downward below the second S/D region 124, and may electrically connect with metallization feature(s) within BSPDN 182.

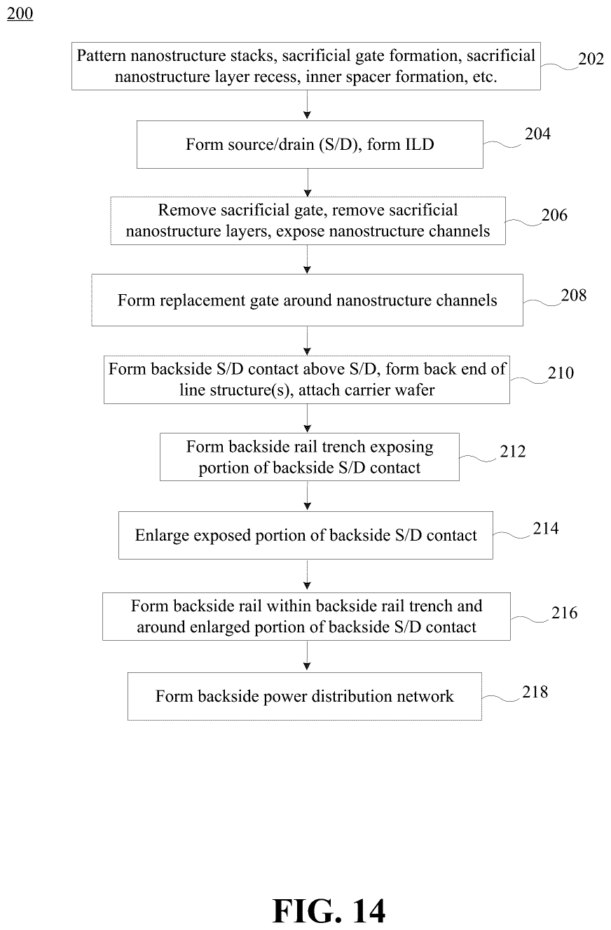

FIG. 14 depicts a method 200 of fabricating semiconductor device 100 that includes a backside S/D contact 161, according to embodiments. Method 200 begins at block 202 with patterning one or more nanostructure stack(s), forming a sacrificial gate structure around the nanostructure stack(s), forming a gate spacer around the sacrificial gate structure, removing nanostructure stack(s) material not protected by the sacrificial gate structure and gate spacer, directionally recessing the sacrificial nanostructure layers of the nanostructure stack that are under the gate spacer, and forming inner spacers within the recesses formed by the directional spacing.

At block 204, respective S/D regions 124 are formed on either side of the nanostructure stack. For example, a first S/D region 124 is formed on a first side of the sacrificial gate contacting first end surfaces of the active semiconductor layers 108 thereunder and a second S/D region 124 is formed on a second side of the sacrificial gate contacting second end surfaces of the active semiconductor layers 108.

At block 206, the sacrificial gate structure is removed, the sacrificial nanostructure layers within the nanostructure stack are removed, and the active semiconductor layers (i.e., the nanostructure channels) are exposed. For example, sacrificial gate 116 is removed, sacrificial layers 106 are removed, and active semiconductor layers 108 are exposed. At block 208, a replacement gate structure 135 is formed around the nanostructure channels. For example, WMF gate 134 is formed around the exposed active semiconductor layers 108.

At block 210, a backside S/D contact 161 is formed above or over the first S/D region, BEOL structures are formed over the first S/D contact, and a carrier wafer is attached to the top surface or front side of the semiconductor device 100. For example, backside S/D contact 161 is formed upon and contacts the top surface of the first S/D region 124, extends laterally beyond the perimeter of the first S/D region 124, and extends vertically downward below the bottom surface of the first S/D region 124. After backside S/D contact 161 formation, BEOL structures 162 are formed over the S/D contact 160, and carrier wafer 166 is attached.

In examples, bottom substrate 102 and insulator layer 104 may be removed, upper substrate 105 may be recessed, and an ILD 170 may be formed. At block 212, backside rail trench 171 may be formed within ILD 170 that exposes at least the bottom portion of backside S/D contact 161. In an example, liner 159 of backside S/D contact 161 may be removed from the exposed bottom portion of backside S/D contact 161 within backside rail trench 171.

At block 214, the exposed bottom portion of backside S/D contact 161 may be enlarged by forming S/D contact mushroom 172 there around within backside rail trench 171. At block 216, backside rail 180 is formed around the S/D contact mushroom 172 within backside rail trench 171. At block 218, BSPDN 182 is formed upon the backside rail 180.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
an substrate layer;
a transistor upon the substrate layer, the transistor includes both one or more channel regions and a first source or drain (S/D) region upon the substrate layer, the first S/D region connected to the one or more channel regions;
a backside S/D contact connected to a top surface of the first S/D region, the backside S/D contact comprising both a lateral portion that laterally extends adjacent to the first S/D region and a vertical portion that extends vertically downward below the bottom surface of the substrate layer; and
a backside S/D mushroom that extends vertically downward below the vertical portion.

2. The semiconductor device of claim 1, further comprising:
a backside rail around the backside S/D mushroom.

3. The semiconductor device of claim 2, wherein the backside rail comprises an internal conductive region and a conductive barrier liner between the internal conductive region and the backside S/D mushroom.

4. The semiconductor device of claim 1, further comprising:
a shallow trench isolation (STI) region around the backside S/D contact between the first S/D region and the backside rail.

5. The semiconductor device of claim 4, wherein the backside S/D reduces electrical impedance from the backside rail to the backside S/D contact.

6. The semiconductor device of claim 5, wherein the transistor is a gate all around nanosheet structure that includes a plurality of channel regions each surrounded by one work function metal gate.

7. The semiconductor device of claim 6, wherein the vertical portion of the backside S/D contact is between adjacent gate cut regions.

8. The semiconductor device of claim 1, wherein the backside S/D contact is formed of a first conductive metal and the backside S/D mushroom is also formed of the first conductive metal.

9. The semiconductor device of claim 1, wherein the backside S/D contact is formed of a first conductive metal and the backside S/D mushroom is formed of a second conductive metal with higher conductivity relative to the first conductive metal.

10. The semiconductor device of claim 1, further comprising:
a second S/D region upon the substrate layer and connected to the one or more channel regions;
a frontside S/D region contact upon connected to the top surface of the second S/D region; and
a metallization feature within a back end of the line (BEOL) level electrically connected to the frontside S/D region contact.

11. A method of forming a semiconductor device, the method comprising:
forming a source or drain (S/D) region upon a substrate layer and contacting respective first end(s) of one or more channel regions;
forming a backside S/D contact upon a top surface of the S/D region, the backside S/D contact extending laterally adjacent to the S/D region, the backside S/D contact extending vertically downward below the bottom surface of the substrate layer;
forming a backside rail trench that exposes a portion of the backside S/D contact; and
forming a backside S/D mushroom from the exposed portion of the backside S/D contact, the backside S/D mushroom extending vertically downward below the backside S/D contact.

12. The semiconductor device fabrication method of claim 11, further comprising:
forming a backside rail around the backside S/D mushroom within the backside rail trench.

13. The semiconductor device fabrication method of claim 12, wherein the backside rail comprises an internal conductive region and a conductive barrier liner between the internal conductive region and the backside S/D mushroom.

14. The semiconductor device fabrication method of claim 11, further comprising:
partially recessing the substrate layer; and
forming a shallow trench isolation (STI) region within the partial recess of the substrate layer, wherein the backside S/D contact is formed within the STI region.

15. The semiconductor device fabrication method of claim 14, wherein the backside S/D reduces electrical impedance from the backside rail to the backside S/D contact.

16. The semiconductor device fabrication method of claim 15, wherein the transistor is a gate all around nanosheet structure that includes a plurality of channel regions each surrounded by one work function metal gate.

17. The semiconductor device fabrication method of claim 16, wherein the vertical portion of the backside S/D contact is between adjacent gate cut regions.

18. The semiconductor device fabrication method of claim 14, further comprising:
forming an interlayer dielectric (ILD) upon the substrate layer and upon the STI region, wherein the backside rail trench is formed within the ILD and within the STI region.

19. The semiconductor device fabrication method of claim 11, wherein the backside S/D contact is formed of a first conductive metal and the backside S/D mushroom is formed of a second conductive metal with higher conductivity relative to the first conductive metal.

20. A transistor comprising:
one or more channel regions;
a single gate that is around each of the one or more channel regions;
a source or drain (S/D) region connected to the one or more channel regions; and
a backside S/D contact connected to a top surface of the S/D region, the backside S/D contact comprising a lateral portion upon the top surface of the S/D region and that laterally extends adjacent to the first S/D region, and a vertical portion that extends vertically downward from the lateral portion below the bottom surface of the substrate layer; and
a backside S/D mushroom that extends vertically downward from the vertical portion.
